(19) United States
(12) Patent Application Publication
(10) Pub. No.: US 2011/0265708 A1
(43) Pub. Date: Nov. 3, 2011

(54) METHOD OF HETEROEPITAXY

(75) Inventor: Ken SATO, Niiza-shi (JP)

(73) Assignee: Sanken Electric Co., Ltd., Niiza-shi (JP)

(21) Appl. No.: 13/094,274

(22) Filed: Apr. 26, 2011

(30) Foreign Application Priority Data
Apr. 30, 2010 (JP) 2010-105009

(51) Int. Cl. C30B 19/12; C30B 23/02; C30B 25/18

(52) U.S. Cl. 117/58; 117/95; 117/106

(57) ABSTRACT

Epitaxy is carried out by immersing a single crystal substrate having a first principal surface, a second principal surface and a dislocation exposed on the first principal surface into an electrolytic solution including a cation of a metal having a melting point; carrying out electrolytic plating on the first principal surface to deposit the metal on the dislocation so as to cover the dislocation with the metal but leave a portion of the first principal surface where the dislocation is exposed uncovered with the metal; and causing epitaxy of a semiconductor layer on both the portion of the first principal surface and the metal covering the dislocation at a temperature below the melting point.

### CROSS-REFERENCE TO RELATED APPLICATIONS

This application is based upon and claims the benefit of priority from the prior Japanese Patent Application No. 2010-105009 (filed Apr. 30, 2010); the entire contents of which are incorporated herein by reference.

### BACKGROUND OF THE INVENTION

1. Field of the Invention

The present invention relates to a method of epitaxy for producing a substrate applicable to production of a compound semiconductor device.

2. Description of the Related Art

III-V compound semiconductors remain promising materials for producing semiconductor lasers, light emission diodes (LED), photo diodes and various devices. Representative III-V compound semiconductors are aluminum-Indium-Gallium nitride semiconductors, which include aluminum nitride, gallium nitride and indium nitride, and can be expressed by a general formula of AlₓIn_{y}Ga_{1-x-y}N.

Heteroepitaxy is applicable to production of III-V compound semiconductors. This method uses a substrate, usually of a single crystal of a semiconductor having a lattice structure similar to that of a desired compound semiconductor, and grows a single-crystalline film which takes on the lattice structure and orientation of the substrate.

Japanese Patent Unexamined Publication No. 2008-303136 discloses a related art of epitaxy, in which metal layers are embedded in a grown semiconductor film.

### SUMMARY OF THE INVENTION

There may be considerable room for improvement of quality of epitaxial films in view of, for example, density of dislocations. Densities of dislocations in films produced by the aforementioned related art are thought to be 10⁴ per cm² or more for instance.

The present invention has been achieved in the aforementioned viewpoint. According to an aspect of the present invention, epitaxy is carried out by immersing a single crystal substrate having a first principal surface, a second principal surface and a dislocation exposed on the first principal surface into an electrolytic solution including a cation of a metal having a melting point; carrying out electrolytic plating on the first principal surface to deposit the metal on the dislocation so as to cover the dislocation with the metal but leave a portion of the first principal surface where the dislocation is exposed uncovered with the metal; and causing epitaxy of a semiconductor layer on both the portion of the first principal surface and the metal covering the dislocation at a temperature below the melting point.

### BRIEF DESCRIPTION OF THE DRAWINGS

FIGS. 1A through 1D are schematically shown cross sectional view of a substrate and an epitaxial film thereon, which illustrate a sequence of film growth according to an embodiment of the present invention;

FIG. 2 is a schematic drawing of electrolytic plating carried out in the film growth;

FIG. 3 is a schematic drawing of electrolytic plating of a modified version;

FIG. 4 is a schematic drawing of electrolytic plating of a further modified version;

FIG. 5 is a schematically shown cross sectional view of a substrate applicable to the film growth; and

FIG. 6 is a schematically shown cross sectional view of a substrate of a modified version.

### DETAILED DESCRIPTION OF THE PREFERRED EMBODIMENT

Certain embodiments of the present invention will be described hereinafter with reference to the appended drawings. It is noted that the drawings are not scaled and therefore dimensions are not limited to those shown therein.

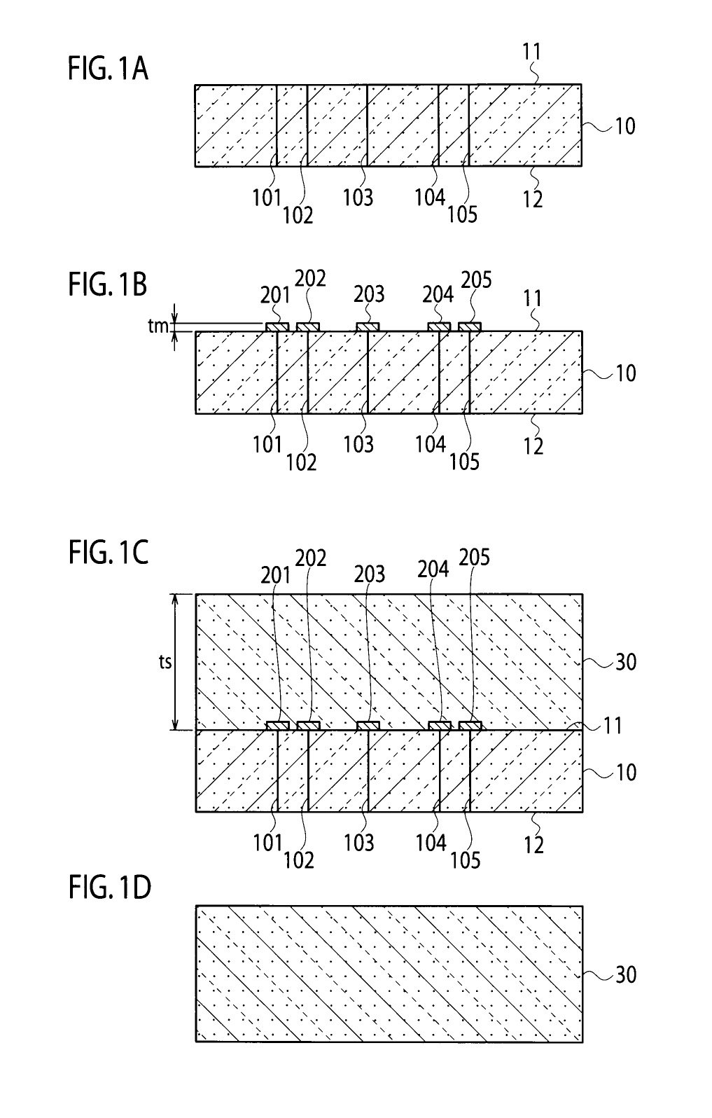

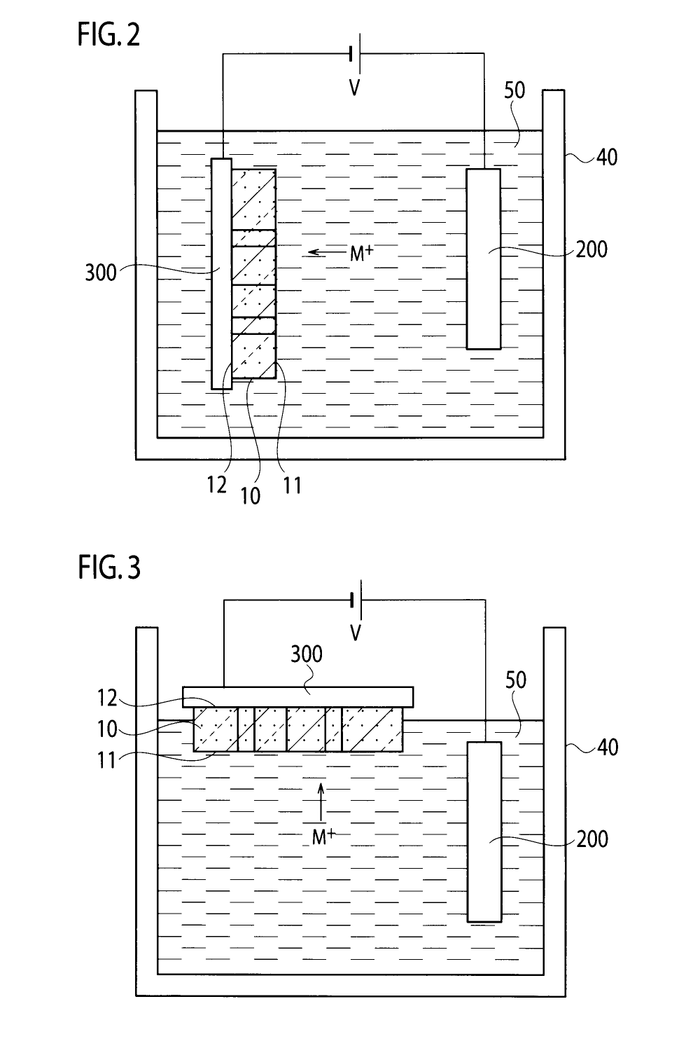

A method according to an embodiment of the present invention is preferably applicable to film growth of semiconductors, such as III-V compound semiconductors. The method is a kind of epitaxy, which is comprised of steps of: immersing a single crystal substrate 10 having a first principal surface 11, a second principal surface 12 opposed to the first principal surface 11 and dislocations 101-105 exposed on the first principal surface 11, as shown in FIG. 1A, into an electrolytic solution, as shown in FIG. 2-4; carrying out electrolytic plating on the first principal surface to deposit islands 201-205 of a metal M on the dislocations 101-105 so as to cover the dislocations with the metal but leave a portion of the first principal surface 11 where the dislocations are not exposed without the dislocation uncovered with the metal as shown in FIG. 1B; and causing epitaxy of a semiconductor layer 30 on both the uncovered first principal surface 11 and the metal covering the dislocation as shown in FIG. 1C. While the substrate 10 with the semiconductor layer 30 can be available for production of a semiconductor device, the substrate 10 may be removed so as to use the semiconductor layer 30 alone as shown in FIG. 1D.

This method employs a single crystal preferably of a semiconductor having a lattice structure and a lattice constant sufficiently close to those of the semiconductor layer 30. Any single crystal of III-V compound semiconductors such as aluminum nitride, gallium nitride and indium nitride are applicable. The single crystal is preferably doped to have a resistivity of 10⁴ Ω·cm or higher so as to cause preferential growth of the metal on dislocations, details of which will be described later.

The single crystal is cut and polished to form the substrate 10 having the first principal surface 11 and the second principal surface 12. Such a substrate may be available from a commercial market. The substrate 10 frequently contains a considerable number of dislocations such as those 101-105 drawn in FIG. 1A.

Referring to FIGS. 2-4, a container 40 stores an electrolytic solution 50 adapted for electrolytic plating, in which a cation of the metal M, expediently notated by “M⁺”, is dissolved. The substrate 10 of the single crystal electrically connected with a cathodic electrode 300 is immersed in the electrolytic solution 50. The cathodic electrode 300 preferably covers the second principal surface 12 thereof. An anodic electrode 200 also serving as a source of the cation M⁺ is also immersed in the solution 50 and then a voltage V is impressed therebetween.

The dislocations 101-105 have electric properties different from those of a bulk of the single crystal. Further if the bulk of the single crystal is given a sufficiently high resistivity, namely 10⁴ Ω·cm or higher as described above, current preferentially flows through the dislocations 101-105 exposed on the first principal surface 11. As the cation M⁺ migrates along the current flow and then causes deposition of the metal M, metal islands 201-205 preferentially grow respectively on the dislocations 101-105 as shown in FIG. 1B. The metal is deposited just on the dislocations 101-105, and further on these peripheries. The deposition may occur within the dislocations 101-105 as well. The widths of the metal islands are in general in the order of several through several tens nanometers. Further the thickness tm of the metal islands 201 should be properly controlled in the same order.

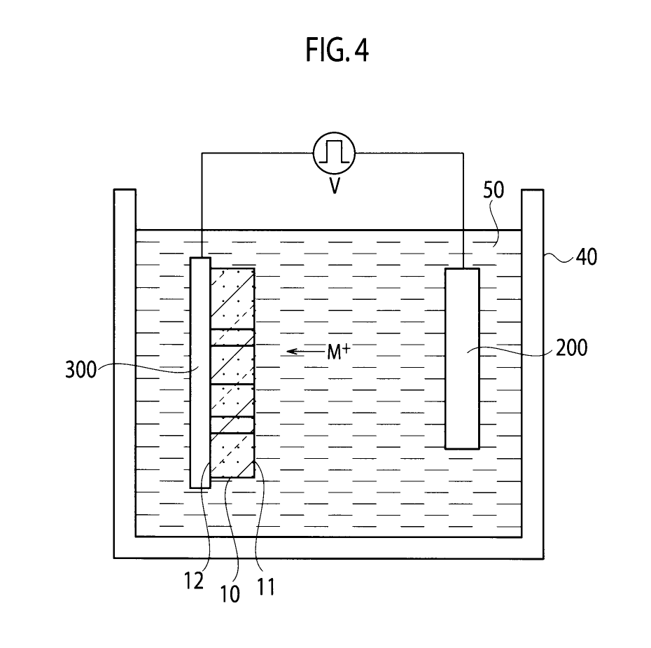

The electrolytic plating as described above may be modified in some ways. The cathodic electrode 300 along with the substrate 10 may be immersed in the solution 50 as shown in FIG. 2. Alternatively, the substrate 10 alone may be immersed therein and the electrode 300 may be kept out of the solution 50 as shown in FIG. 3. Further the power supply may supply constant direct current but the power supply alternatively may supply pulse current with a controlled pulse width and a controlled frequency as shown in FIG. 4. This is beneficial for uniform growth of the metal islands 201-205.

To make the resistivity of the substrate 10 be 10⁴ Ω·cm or higher, the original single crystal may be doped with a proper dopant, such as ferrum, magnesium and zinc. The dopant concentration can be exemplified as about 10¹⁸-10²¹ atoms/cm³, in n a case where the single crystal is GaN. In the meantime, only the surface at issue requires such resistivity. Thus instead of doping the bulk, implantation of the dopant into the surface may be used.

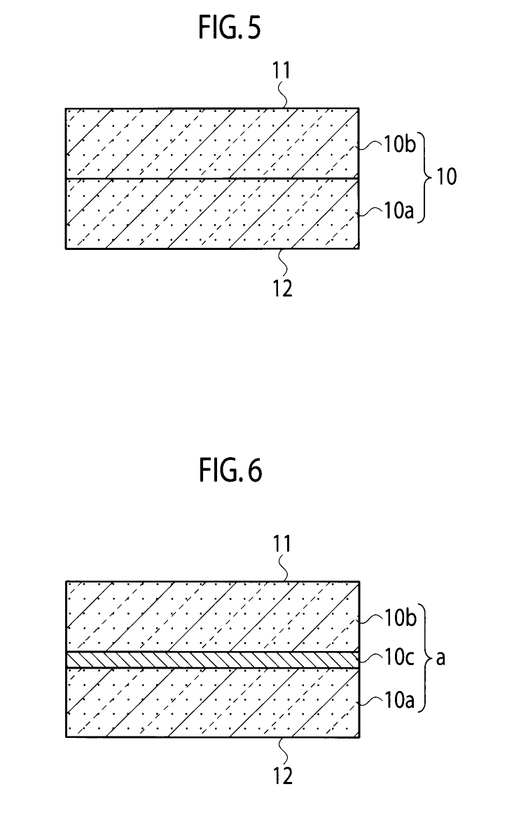

Still alternatively, hybrid substrates such as those shown in FIGS. 5 and 6 may be used. The substrate 10 exemplified in FIG. 5 includes a first region 10a of a proper semiconductor such as silicon carbide and a second region 10b layered thereon, which is of a III-V compound semiconductor having a resistivity of 10⁴ Ω·cm or higher. To give the resistivity to the second region 10b, doping of ferrum, magnesium and zinc may be used as with the case described above. In contrast, some degree of conductivity may be given to the first region 10a in view of assuring sufficient current flow to the cathodic electrode 300.

The substrate 10 exemplified in FIG. 6 includes a first region 10a usable as the second principal surface, a second region 10b usable as the first principal surface, and an interposed layer 10c with sufficient conductivity. As the interposed layer 10c can be employed for electric connection with the cathodic electrode 300, a highly resistive material can be applied to the first region 10a.

The metal M should be properly selected particularly in view of its melting point. As the succeeding epitaxy causes the substrate 30 exposure to a considerably high temperature, the melting point should be higher than the temperature in the epitaxy. Or, alternatively, the temperature to carry out the epitaxy should be regulated below the melting point. In a case where epitaxy of gallium nitride will be executed at about 1100 degrees C., metals with high melting points, such as chromium, nickel and platinum, are preferably applied to the metal M.

Referring to FIG. 1C, epitaxy of the semiconductor layer 30 is executed. Any known epitaxy methods such as hydride vapor phase epitaxy (HVPE), metal organic vapor phase epitaxial growth (MOVPE), molecular beam epitaxy (MBE), a sodium flux method and an ammonothermal method may be applied to the epitaxy. Epitaxial growth may first occur on the first principal surface 11 uncovered with the metal islands 201-205 so as to take on the lattice structure and orientation of the substrate. The growing semiconductor layer 30 comes to cover the metal islands 201-205 and finally an epitaxially grown semiconductor layer 30 is formed on both the uncovered first principal surface 11 and the metal islands 201-205 covering the dislocations 101-105. The thickness ts of the semiconductor layer 30 should be properly controlled. Several tens through several hundreds micrometers can be exemplified as the thickness ts.

Polishing may be executed on the substrate 10 so as to remove the substrate 10 and the metal islands 201-205 as shown in FIG. 1D. Then the semiconductor layer 30 alone is available as a final product. Alternatively, the substrate 10 with the semiconductor layer 30 can be available as a final product.

Epitaxial films produced by the prior art contain a considerable amount of dislocations, which may ill-affect properties of devices made from the films, because growth of the epitaxial films takes on dislocations in the substrate. In contrast, the metal islands 201-205 respectively on the dislocations 101-105 blocks progress of the dislocations into the epitaxial film. Thus the epitaxial film according to the present embodiment has very few crystal defects such as dislocations.

The above description exemplifies heteroepitaxy of III-V compound semiconductors, however, the disclosed method is applicable to any other materials and homoepitaxy, such as a silicon carbide layer on a silicon carbide substrate. The same or similar effects will be enjoyed.

Although the invention has been described above by reference to certain embodiments of the invention, the invention is not limited to the embodiments described above. Modifications and variations of the embodiments described above will occur to those skilled in the art, in light of the above teachings.

What is claimed is:

1. A method of epitaxy, comprising:
immersing a single crystal substrate having a first principal surface, a second principal surface and a dislocation exposed on the first principal surface into an electrolytic solution including a cation of a metal having a melting point;
carrying out electrolytic plating on the first principal surface to deposit the metal on the dislocation so as to cover the dislocation with the metal but leave a portion of the first principal surface, where the dislocation is not exposed, uncovered with the metal; and
causing epitaxy of a semiconductor layer on both the portion of the first principal surface and the metal covering the dislocation at a temperature below the melting point.

2. The method of claim 1, further comprising:
covering and electrically connecting the second principal surface with a cathodic electrode.

3. The method of claim 1, wherein the semiconductor layer consists essentially of a III-V compound semiconductor.

4. The method of claim 1, wherein the metal consists essentially of one selected from the group consisting of chromium, nickel and platinum.

5. The method of claim 1, wherein the substrate at least at the first principal surface has a resistivity of 10⁴ Ω·cm or higher.

6. The method of claim 1, wherein the substrate consists essentially of a doped III-V compound semiconductor with a dopant selected from the group consisting of ferrum, magnesium and zinc.

7. The method of claim 1, wherein the substrate includes a primary substrate and a doped III-V compound semiconductor layer with a dopant selected from the group consisting of ferrum, magnesium and zinc, the doped III-V compound semiconductor layer being deposited on the primary substrate.

8. The method of claim 1, further comprising:
removing the substrate from the semiconductor layer.

9. The method of claim 1, wherein the metal is deposited on the dislocation and peripheries of the dislocation.

10. The method of claim 1, wherein the metal is deposited within and on the dislocation.
